(19) United States
(12) Patent Application Publication
(10) Pub. No.: US 2008/0210544 A1
(43) Pub. Date: Sep. 4, 2008

(54) METHOD FOR MANUFACTURING A MAGNETIC TUNNEL JUNCTION SENSOR USING ION BEAM DEPOSITION

(76) Inventor: Mustafa Michael Pinarbasi, Morgan Hill, CA (US)

Correspondence Address: ZILKA-KOTAB, PC- HIT, P.O. BOX 721120, SAN JOSE, CA, 95172-1120, US

(21) Appl. No.: 11/848,104

(22) Filed: Aug. 30, 2007

Related U.S. Application Data
(63) Continuation-in-part of application No. 11/615,887, filed on Dec. 22, 2006.

(51) Int. Cl. C23C 14/34

(52) U.S. Cl. 204/192.11

(57) ABSTRACT

A method for forming a MgOₓ barrier layer in a magnetic tunnel junction (MTJ) sensor, also known in the art as a tunneling magnetoresistance (TMR) sensor. The MgOₓ barrier layer is deposited by an ion beam deposition (IBD) process that results in a MgOₓ barrier layer having exceptional, uniform properties and a well-controlled oxygen content. The ion beam deposition of the barrier layer includes placing a wafer into an ion beam deposition (IBD) chamber provided with a Mg target. An ion beam from an ion gun is directed at the target thereby sputtering Mg atoms from the target for deposition onto the wafer. Oxygen is admitted into the chamber as one or both of two species: molecular oxygen, O₂, admitted through a gas inlet, and oxygen ions, admitted through a second ion gun, The use of ion beam deposition avoids oxygen poisoning of the Mg target, such as would occur using a more conventional plasma vapor deposition (PVD) technique.

### RELATED APPLICATIONS

This application is a continuation in part (CIP) of U.S. patent application Ser. No. 11/615,887, filed Dec. 22, 2006 entitled METHOD FOR MANUFACTURING A MAGNETIC TUNNEL JUNCTION SENSOR USING ION BEAM DEPOSITION, the content of which is hereby incorporated by reference in its entirety for all purposes as if fully set forth herein.

### FIELD OF THE INVENTION

The present, invention relates to the construction of a magnetic tunnel junction (MTJ) sensor and more particularly to a method for constructing a barrier layer that improves the performance of the sensor.

### BACKGROUND OF THE INVENTION

The heart of a computer's long-term memory is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected circular tracks on the rotating disk. The read and write heads are directly located cm a slider that has an air-bearing surface (ABS). The suspension arm biases the slider toward the surface of the disk and when the disk rotates, air adjacent to the surface of the disk moves along with the disk. The slider flies on this moving air at a very low elevation (fly height) over the surface of the disk. This fly height can be on the order of Angstroms. When the slider rides on the air bearing, the write and read heads are employed for writing magnetic transitions to and reading magnetic transitions from the rotating disk. The read and write heads are connected to processing circuitry that operates according to a computer program to implement the writing and reading functions.

The write head includes a coil layer embedded in first, second and third insulation layers (insulation stack), die insulation stack being sandwiched between first and second pole piece layers. A gap is formed between the first and second pole piece layers by a gap layer at an air-bearing surface (ABS) of the write head and the pole piece layers are connected at a back gap. Current conducted to the coil layer induces a magnetic flux in the pole pieces which causes a magnetic field to fringe out at a write gap at the ABS for the purpose of writing the aforementioned magnetic impressions in tracks on the moving media, such as in circular tracks on the aforementioned rotating disk.

In recent read head designs a spin valve sensor, also referred to as a giant magnetoresistive (GMR) sensor, has been employed for sensing magnetic fields from the rotating magnetic disk. This sensor includes a nonmagnetic conductive layer, referred to as a spacer layer, sandwiched between first and second, ferromagnetic layers, and hereinafter referred to as a pinned layer and a free layer. First and second leads are connected to the spin valve sensor for conducting a sense current therethrough. The magnetization of the pinned layer is pinned perpendicular to the air-bearing surface (ABS) and the magnetic moment of the free layer is biased parallel to the ADS, but is free to rotate in response to external magnetic fields. The magnetization of the pinned layer is typically pinned by exchange coupling with an antiferromagnetic layer.

The thickness of the spacer layer is chosen to be less than the mean free path of conduction electrons through the sensor. With this arrangement, a portion of the conduction electrons is scattered by the interfaces of the spacer layer with each of the pinned and free layers. When the magnetizations of the pinned and free layers are parallel with respect to one another, scattering is minimal and when the magnetizations of the pinned and free layer are antiparallel, scattering is maximized. Changes in scattering alter the resistance of the spin valve sensor in proportion to cos θ, where θ is the angle between the magnetizations of the pinned and free layers. In a read mode, the resistance of the spin valve sensor changes proportionally to the magnitudes of the magnetic fields from the rotating disk. When a sense current is conducted through the spin valve sensor, resistance changes cause potential changes that are detected and processed as read back signals.

More recently, researchers have focused on the development of magnetic tunnel junction (MTJ) sensors, also referred to as tunneling magnetoresistance (TMR) sensors or tunnel valves. Tunnel valves or MTJ/TMR sensors offer the advantage of providing improved signal amplitude as compared with other GMR sensors. MTJ/TMR sensors operate based on the spin dependent tunneling of electrons through a thin, electrically insulating barrier layer. The structure of the barrier layer is critical to optimal MTJ/TMR sensor performance, and certain manufacturing difficulties such as target poisoning during barrier layer deposition have limited the effectiveness of such MTJ/TMR sensors. Therefore, there is a strong felt need for a magnetic tunnel junction (MTJ) sensor that can provide optimal MTJ/TMR performance, and also, for a practical, method of manufacturing such an optimized MTJ/TMR sensor.

### SUMMARY OF THE INVENTION

The present invention provides a method for forming a MgOₓ barrier layer in a magnetic tunnel junction (MTJ), or tunneling magnetoresistance (TMR), sensor. An exemplary MTJ/TMR sensor is a bottom type tunnel valve with a pinned layer structure at the bottom of the layers constituting the sensor stack. The MgOₓ barrier layer can be deposited by placing a wafer in the chamber of an ion beam deposition system. An ion beam from a first ion gun is directed at a Mg target located within the chamber, thereby sputtering Mg atoms from the target for transport and deposition onto a wafer substrate. While the ion beam is depositing Mg onto the wafer substrate, oxygen is admitted into the chamber.

The oxygen reacts with the deposited Mg to form a well-controlled MgOₓ layer. The oxygen can be admitted into the chamber as molecular oxygen, 0% gas through a gas inlet. Alternatively or additionally, the oxygen can be admitted into the chamber as ionized or molecular oxygen, O₂, through a second ion gun depending on whether, or not, the ionization chamber of the gun is activated. The second gun is arranged to direct a stream of oxygen gas, or beam of oxygen ions, at the wafer substrate.

The ion beam deposition of MgOₓ advantageously deposits a high quality, uniform barrier layer to form a MTJ/TMR sensor. The ion beam deposition (IBD) avoids the target poisoning that occurs when using the more standard plasma vapor deposition (PVD) technique to deposit MgOₓ. Such target poisoning, which occurs with plasma vapor deposition, results when oxygen from the plasma, formed within the chamber, deposits on and reacts with the target. Since the ion beam deposition (IBD) technique does not include striking a plasma within the chamber, such target poisoning does not occur when using the method of the present invention.

These and other advantages and features of the present invention will be apparent upon reading the following detailed description in conjunction with the Figures.

### BRIEF DESCRIPTION OF THE DRAWINGS

For a fuller understanding of the nature and advantages of this invention, as well as the preferred mode of use, reference should be made to the following detailed description read in conjunction with the accompanying drawings that are not to scale.

FIG. 1 is a schematic illustration of a disk drive system in which the invention might be embodied;

FIG. 2 is an ABS view of a slider, taken from line 3-3 of FIG. 2, illustrating the location of a magnetic head thereon;

FIG. 3 is an ABS view of a magnetic tunnel junction (MTJ), tunneling magnetoresistance (TMR), sensor according to an embodiment of the present invention taken from circle 3 of FIG. 2;

FIG. 4 is a schematic view of an ion beam deposition chamber for use in depositing a MgOₓ barrier layer in a magnetic tunnel junction (MTJ), tunneling magnetoresistance (TMR), sensor;

FIG. 5 is a flow chart illustrating a method of depositing a MgOₓ barrier layer according to an embodiment of the invention; and

FIG. 6 is a flow chart illustrating a method of depositing a MgOₓ barrier layer according to an alternate embodiment of the invention.

### DETAILED DESCRIPTION OF THE INVENTION

The following is a description of embodiments presently contemplated for carrying out this invention. This description is made for the purpose of illustrating the general principles of this invention and is not meant to limit the inventive concepts claimed herein.

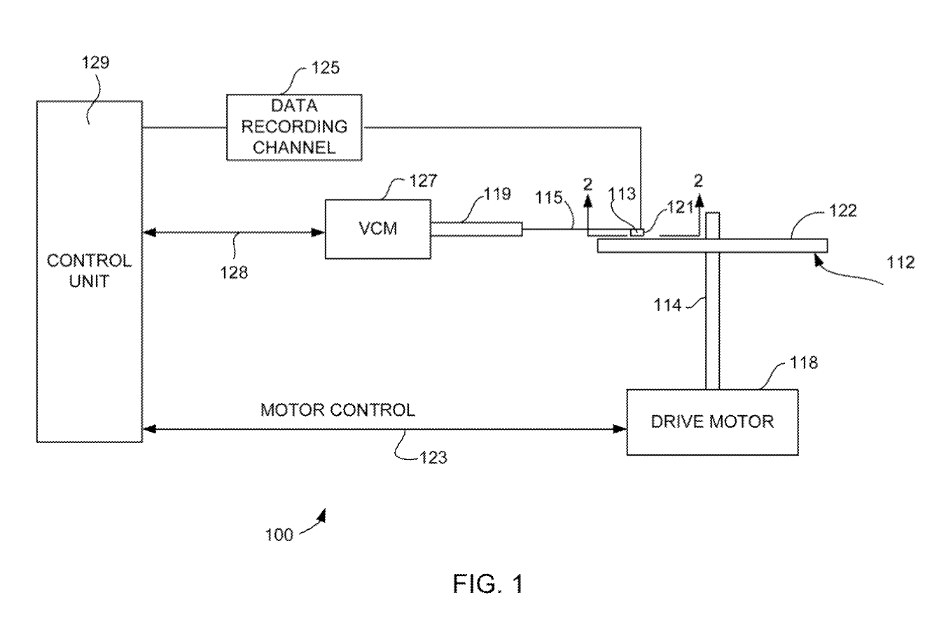

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves radially in and out over the disk surface 122 so that the magnetic head assembly 121 may access different tracks of the magnetic disk where desired data are written. Each slider 113 is attached to an actuator arm 119 by way of a suspension 115. The suspension 115 provides a slight spring force, which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed, of the coil movements being controlled by the motor current signals supplied by controller 129.

During operation of the disk storage system, the rotation of the magnetic disk 112 generates an air bearing between the slider 113 and the disk surface 122, which exerts an upward force or lift on the slider. The air bearing thus counter-balances die slight spring force of suspension 115 and supports slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control Signals on line 128. The control signals on line 128 provide the desired current profiles to optimally move and position slider 113 to the desired data track on disk 112. Write and read signals are communicated to and from write and read heads 121 by way of recording channel 125.

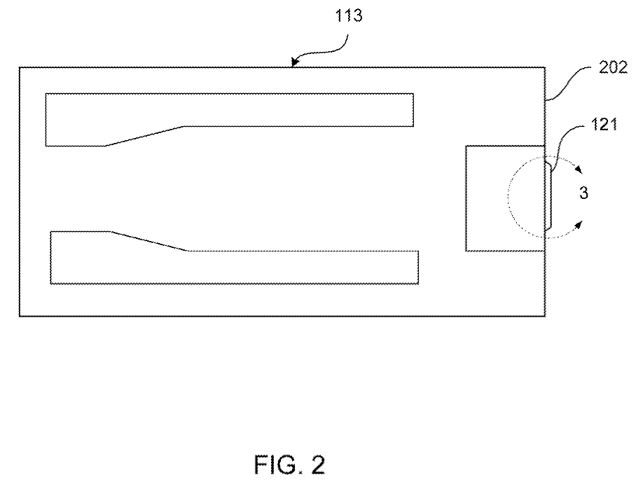

With reference to FIG. 2, the orientation of the magnetic head 121 in a slider 113 can be seen in more detail. FIG. 2 is an ABS view of the slider 113, and as can be seen, the magnetic head including an inductive write head and a read sensor, is located at a trailing edge of the slider 202. The above description of a typical magnetic disk storage system, and the accompanying illustration of FIG. 1 are for representation purposes only. It should be apparent that disk storage systems may contain a large number of disks and actuators, and each actuator may support a number of sliders.

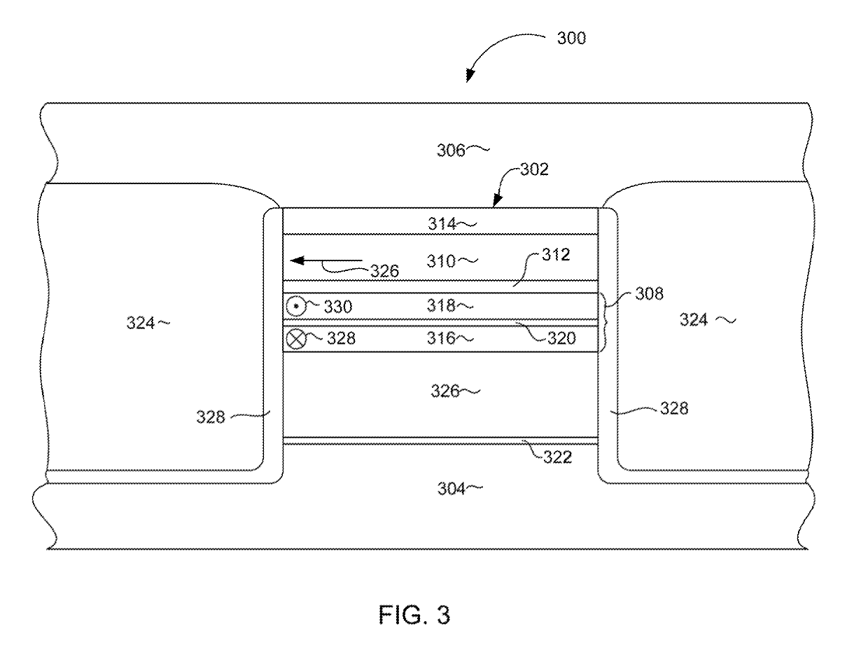

With reference now to FIG. 3, a magnetic tunnel junction (MTJ), or tunneling magnetoresistance (TMR), sensor 300 is described. The MTJ/TMR sensor 300 includes a sensor stack 302 sandwiched between first and second electrically conductive leads 304, 306. The leads 304, 306 can be constructed of an electrically conductive, magnetic material such as Ni—Fe alloy or Co—Fe alloy so that they can function as magnetic shields as well as leads. The sensor stack 302 includes a magnetic pinned layer structure 308, and a magnetic free layer structure 310. A thin, non-magnetic, electrically insulating barrier layer 312 is sandwiched between the pinned layer structure 308 and the free layer structure 310. The barrier layer 312 is constructed from an oxide of magnesium, MgOₓ, which may be a sub-stoichiometric or super-stoichiometric oxide as indicated by the subscript “x”, and could have a thickness of 8 to 10 Angstroms, although other thicknesses could be used too.

The pinned layer can include first and second magnetic layers AP1 316 and AP2 318 that are antiparallel coupled across a non-magnetic antiparallel-coupling layer 320. The AP1 and AP2 layers 316, 318 can be constructed of for example, Co—Fe alloy, Co—Fe—B alloy or other magnetic alloys and the antiparallel coupling layer 320 can be constructed of, for example, Ru. The free layer 310 can be constructed of a material such as Co—Fe alloy. Co—Fe—B alloy or Ni—Fe alloy or may be a combination of these or other materials.

The API layer 316 is in contact with and exchange coupled with a layer of antiferromagnetic material (AFM layer) 326 such as Pt—Mn alloy, Ir—Mn alloy, Ir—Mn—Cr alloy, or some other antiferromagnetic material. This exchange coupling strongly pins the magnetization of the AP1 layer 316 in a first direction as indicated by arrow tail 328. Antiparallel coupling between the AP1 and AP2 layers 316, 318 strongly pins the magnetization of the AP2 layer in a second direction perpendicular to the ABS as indicated by arrowhead 330.

A capping layer 314 such as Ta, Ta/Ru or Ru/Ta/Ru may be provided at the top of the sensor stack 302 to protect the layers thereof from damage during manufacture. In addition, a seed layer 322, such as Ta, Ta/Ru, or Ni—Fe—Cr alloy, may be provided at the bottom of the sensor stack 302 to initiate a desired crystalline growth in the above deposited layers of the sensor stack 302.

First and second hard bias layers 324 may be provided at either side of the sensor stack 302. The hard bias layers 324 can be constructed, of a hard magnetic material such as Co—Pt alloy, or Co—Pt—Cr alloy, deposited on suitable seed layers and under layers such as Cr, Cr—Mo alloy, or other Cr alloys. These hard bias layers 324 are magnetostatically coupled with the free layer 310 and provide a magnetic bias field that biases the magnetization of the free layer 310 in a desired direction parallel with the ABS as indicated by arrow 326. The hard bias layers 324 can be separated from the sensor stack 302 and from at least one of the leads 304 by a layer of electrically insulating material 328 such as alumina in order to prevent current from being shunted across the hard bias layers 324 between the leads 304, 306.

The MgOₓ barrier layer 312 has excellent uniformity, and is deposited by a novel deposition method that will be described in detail herein below and which results in an improved resistance-area product (RA) value and tunneling magnetoresistance (TMR) ratio value. In fact, a MTJ/TMR sensor constructed according to this embodiment can have a TMR ratio value of 81.6% to 110% for resistance-area product (RA) values of 1.5-3.1 ohms-micron², which is quite good.

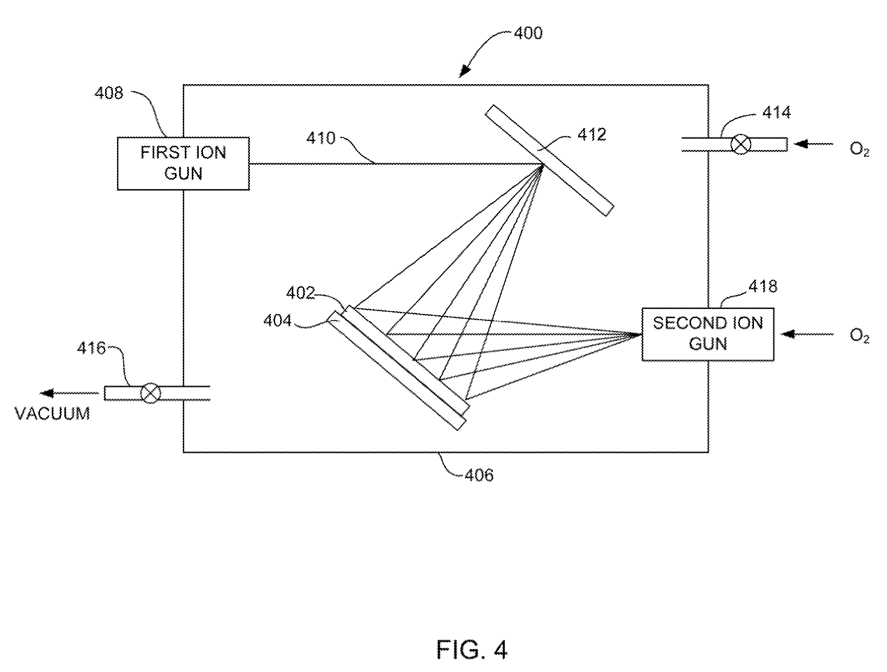

With reference now to FIG. 4, a novel method for depositing the barrier layer 312 (FIG. 3) is described. The above-described layers of the sensor stack 302 (FIG. 3) can be deposited in an ion beam deposition (IBD) tool 400. The sensor layers are deposited on a wafer 402 that is held on a chuck 404 inside an ion beam deposition chamber 406. The following description of a method for depositing a MgOₓ barrier layer 312 (FIG. 3) assumes that the AFM layer 326 and pinned layer structure 308 of the sensor stack have already been deposited, so that the barrier layer can be deposited over the pinned layer structure 308.

With reference still to FIG. 4, the IBD tool 400 includes first ion gun 408 that directs an ion beam 410 at a target 412, which in this case is composed of metallic Mg. The ion gun 408 is fed with a noble gas, such as argon (Ar), krypton (Kr), or xenon (Xe), which is ionized within the gun and accelerated toward the target 412. Ions from the ion beam 410 cause Mg atoms to sputter from the target and deposit onto the wafer substrate 402. While the ion gun 408 is bombarding the target 412 with ions 410, molecular oxygen, is being admitted into the chamber 406 through gas inlet 414. An outlet 416 may also be provided for pumping the chamber 406 at such a rate so as to maintain within the chamber a specified pressure of the O₂ gas admitted through the gas inlet 414. The O₂ admitted into the chamber 406 reacts with the Mg sputtered from the target on the surface of the wafer substrate 402 to form a deposited layer of MgOₓ thereon. Through the methods known in the art for careful control of the chamber background pressure of molecular oxygen, O₂, by regulating the pumping speed through the outlet 416 and the flow rate of O₂ gas admitted through the inlet 414, and of the sputtering rate of the Mg target, the relative amounts of Mg and O in the deposited MgOₓ layer can be adjusted in an extremely controllable and uniform manner.

The above-described IBD deposition of MgOₓ differs significantly from a more conventional plasma vapor deposition (PVD) of MgOₓ. In a plasma vapor deposition tool, a plasma would be struck, in the chamber itself in the presence of oxygen. Then, MgOₓ would be deposited from a Mg target. This method, however, does not result in a well-controlled barrier layer deposition process, because of target oxidation. When the target oxidizes, the deposition rate drops significantly. This is due to the fact that oxygen from the plasma poisons the target, forming MgOₓ, so that Mg can no longer be as effectively sputtered as from an unoxidized metal target. As is well known to those skilled in the art, sputtering with a plasma, as in the PVD technique, is highly dependent on the dielectric properties of the target, and consequently on the presence of oxides on the surface of the target that alter such properties.

In the IBD tool 400 described above, the plasma is generated within the ion gun 408 itself rather than being generated within the chamber 406. Ion beam deposition of MgOₓ as embodied in the present invention avoids the above-described problems associated with plasma vapor deposition (PVD), to produce a MgOₓ barrier having excellent, well-controlled properties.

With continued reference to FIG. 4, a second ion gun 418 can be provided that can be directed at the wafer 402. Whereas the first ion gun 408 can be used to produce an ion beam 410 of such ions as Xe⁺, Ar⁺, or of some other ions suitable for sputtering the target, the second ion gun can be used to produce a second ion beam 420 that includes oxygen ions directed at the wafer 402. The second ion gun 418 receives oxygen as oxygen, O₂, gas that is ionized within the ionization chamber of the ion gun and admitted into the deposition chamber that causes ionized oxygen to envelope the wafer 402 and oxidize the magnesium atoms deposited thereon as these atoms arrive from the Mg target 412 to form a magnesium oxide (MgOₓ) layer. Alternatively, notwithstanding the fact that the ion gun 418 may have the capability of accelerating ionized oxygen toward the wafer substrate 402, the ionized oxygen may be admitted without acceleration. Lacking momentum otherwise provided by acceleration, energetic particle bombardment of the wafer substrate, which may deteriorate the barrier layer, is thereby avoided. In another embodiment, the ionized oxygen is accelerated toward the wafer substrate 402 by tire ion gun 418. Admitting oxygen by means of ion gun 418 can be used in addition to, or in. lieu of, the admission of molecular oxygen, O₂, into the chamber through gas inlet 414.

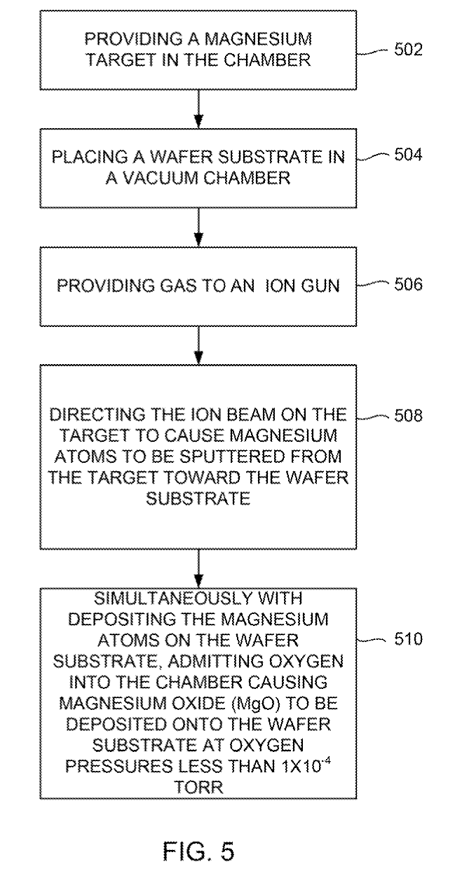

With reference to FIG. 5, a method for depositing a MgOₓ barrier on a TMR sensor stack is described as follows. First, in a step 502, a magnesium target is provided in the vacuum chamber. In a step 504 a wafer substrate is placed in a vacuum chamber of an ion beam deposition (IBD) tool. Then, in a step 506, gas is provided to an ion gun. In a step 508, an ion beam from the ion gun is directed at the target to sputter magnesium atoms toward the substrate. While directing the ion beam at the target, in a step 510, oxygen is admitted into the chamber at a low pressure less than 1×10⁻⁴ Torr, preferably in a range of 6×10⁻⁶ to 2×10⁻⁵ Torr, or about 9×10⁻⁶ Torr. This oxygen can react with the sputtered magnesium atoms arriving at the wafer to deposit a layer of magnesium oxide (MgOₓ) onto the wafer substrate.

The properties of MTJ/TMR sensors, such as TMR ratio, with barrier layers deposited with a high oxygen pressure in the deposition chamber are not as good as those deposited at lower oxygen pressures less than 1×10⁻⁴ Torr. Moreover, the reproducibility and quality of the barrier layer suffers at greater oxygen pressures within the chamber because of oxidation of the Mg target. The oxidation of the Mg target results in the deposition of MgOₓ barrier layers with uncertain and variable composition. The present invention avoids these problems.

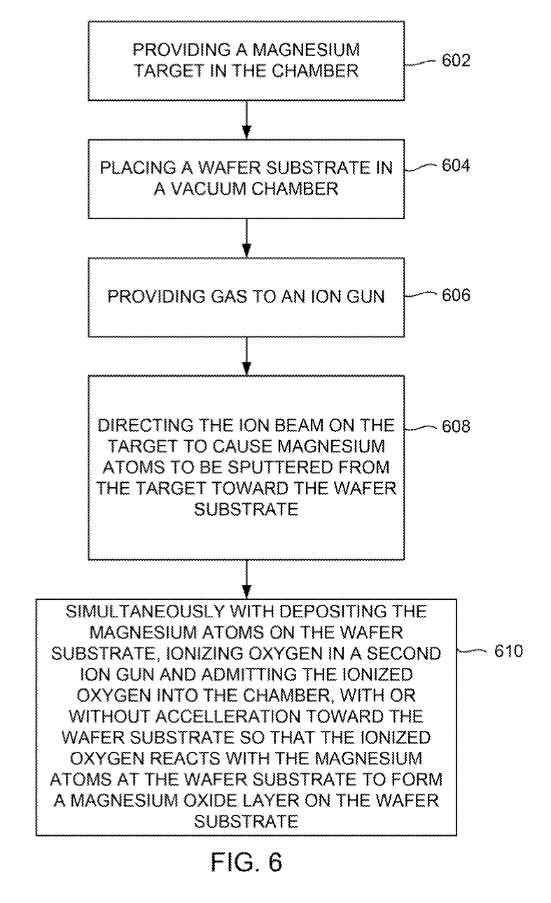

With reference to FIG. 6, another method for depositing a MgOₓ barrier in a TMR sensor is described. In a step 602, a magnesium target is provided in the deposition chamber. In a step 604, a wafer substrate is placed in a deposition chamber of an ion beam deposition (IBD) tool. Then, in a step 606, gas is provided to an ion gun. In a step 608, an ion beam from the ion gun is directed at the target to sputter magnesium atoms toward the wafer substrate. While directing the ion beam at the target, oxygen is ionized in the ionization chamber of an ion gun and admitted into the chamber. This ionized oxygen can be admitted into the chamber with or without acceleration toward the substrate. The ionized oxygen reacts with the sputtered magnesium atoms arriving at the wafer to deposit a layer of magnesium oxide onto the wafer substrate.

While various embodiments have been described above, it should be understood that they have been presented by way of example only, and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method for manufacturing a magnetic tunnel junction (MTJ) sensor comprising:
providing a Mg target in the chamber;
placing a wafer in an ion beam deposition chamber;
directing an ion beam from an ion gun at the target such that Mg atoms are sputtered from the target and deposited on the wafer; and
simultaneously with directing the ion beam at the target, admitting molecular oxygen, O₂, into the chamber to produce a low oxygen pressure inside the chamber less than 1×10⁻⁴ Torr,

2. A method as in claim 1 wherein the molecular oxygen, O₂, admitted into the chamber produces an oxygen pressure inside the chamber within a range of 6×10⁻⁶ to 2×10⁻⁵ Torr.

3. A method as in claim 1 wherein the molecular oxygen, O₂, admitted into the chamber produces an oxygen pressure inside the chamber of about 9×10⁻⁶ Torr.

4. A method as in claim 1 wherein the directing an ion beam at the target further comprises:
feeding a noble gas from the group consisting of argon (Ar), krypton (Kr) and xenon (Xe) into the ion gun; and
operating the ion gun to ionize the noble gas and accelerate the ionized noble gas to sputter the target.

5. A method for manufacturing a magnetic tunnel junction (MTJ) sensor, comprising:
providing a wafer;
depositing a pinned layer structure on the wafer comprising:
depositing a layer of antiferromagnetic material onto the wafer;
depositing a magnetic pinned layer on the layer of antiferromagnetic material;
depositing a MgOₓ barrier layer on the pinned layer structure; and
depositing a magnetic free layer on the MgOₓ barrier layer; and,
wherein the depositing a MgO₂ barrier layer further comprises:
providing a Mg target in the chamber;
placing the wafer in an ion beam deposition chamber;
directing an ion beam from an ion gun at the target such that Mg atoms are sputtered from the target and deposited on the wafer; and
simultaneously with directing the ion beam at the target, admitting oxygen into the chamber.

6. A method as in claim 5 wherein the oxygen admitted into the chamber is molecular oxygen, O₂.

7. A method as in claim 6 wherein the molecular oxygen, O₂, admitted into the chamber produces a low oxygen pressure inside the chamber less than 1×10⁻⁴ Torr.

8. A method as in claim 6 wherein the molecular oxygen, O₂, admitted into the chamber produces an oxygen pressure inside the chamber within a range of 6×10⁻⁶ to 2×10⁻⁵ Torr.

9. A method as in claim 6 wherein the molecular oxygen, O₂, admitted into the chamber produces an oxygen pressure inside the chamber of about 9×10⁻⁶ Torr.

10. A method as in claim 5 wherein the directing an ion beam at the target further comprises:
feeding a noble gas from the group consisting of argon (Ar), krypton (Kr) and xenon (Xe) into the ion gun; and
operating the first ion gun to ionize the noble gas and accelerate the ionized noble gas to sputter the target.

11. A method for manufacturing a magnetic tunnel junction (MTJ) sensor comprising:
providing a Mg target in the chamber;
placing a wafer in an ion beam deposition chamber;
directing an ion beam from a first ion gun at the target such that Mg atoms are sputtered from the target and deposited on the wafer; and
simultaneously with directing the ion beam at the target, admitting ionized oxygen into the chamber;
wherein the ionized oxygen is admitted into the chamber through a second ion gun,

12. A method as in claim 11 wherein the ionized oxygen is admitted into the chamber without acceleration.

13. A method as in claim 11 wherein the oxygen is admitted into the chamber through a second ion gun that accelerates the oxygen ions toward the wafer.

14. A method as in claim 11 wherein the oxygen is admitted into the chamber through a second ion gun that is directed toward the wafer.

15. A method for manufacturing a magnetic tunnel junction (MTJ) sensor., comprising:
providing a wafer;
depositing a pinned layer structure on the wafer comprising:
depositing a layer of antiferromagnetic material onto the wafer;
depositing a magnetic pinned layer on the layer of antiferromagnetic material;
depositing a MgOₓ barrier layer onto the pinned layer structure; and
depositing a magnetic free layer onto the MgOₓ barrier layer; and,
wherein the depositing a MgOₓ barrier layer further comprises:
providing a Mg target in the chamber;
placing the wafer in an ion beam deposition chamber;
directing an ion beam from a first ion gun at the target such that Mg atoms are sputtered from the target and deposited on the wafer; and
simultaneously with directing the ion beam at the target, admitting ionized oxygen into the chamber.

16. A method as in claim 15 wherein the ionized oxygen is admitted into the chamber through a second ion gun without acceleration.

17. A method as in claim 15 wherein the ionized oxygen is admitted into the chamber through a second ion gun that accelerates the oxygen ions toward the wafer.

18. A method for manufacturing a magnetic tunnel junction (MTJ) sensor comprising:
providing a Mg target in the chamber;
placing a wafer in an ion beam deposition chamber;
directing an ion beam from a first ion gun at the target such that Mg atoms are sputtered from the target and deposited on the wafer; and
simultaneously with directing the ion beam at the target, admitting ionized oxygen and molecular oxygen, O₂, into the chamber;
wherein the ionized oxygen is admitted into the chamber through a second ion gun.

19. A method as in claim 18, wherein the molecular oxygen, O₂, is admitted into the chamber from a gas inlet.

20. A method as in claim 16 wherein the ionized oxygen is admitted into the chamber through a second ion gun without acceleration.

21. A method as in claim 16 wherein the ionized oxygen is admitted into the chamber through a second ion gun that accelerates the ions toward the wafer, and wherein the molecular oxygen, O₂, is admitted into the chamber from a gas inlet.
